(19) United States
(12) Patent Application Publication
(10) Pub. No.: US 2025/0132540 A1
(43) Pub. Date: Apr. 24, 2025

(54) LIGHT-EMITTING DEVICE, METHOD FOR MANUFACTURING LIGHT-EMITTING DEVICE, AND DISTANCE MEASUREMENT DEVICE

(71) Applicant: SONY SEMICONDUCTOR SOLUTIONS CORPORATION, Kanagawa (JP)

(72) Inventor: Tomoki HIRANO, Kanagawa (JP)

(21) Appl. No.: 18/836,174

(22) PCT Filed: Jan. 19, 2023
(86) PCT No.: PCT/JP2023/001559

§ 371 Date: Aug. 6, 2024

(30) Foreign Application Priority Data
Feb. 8, 2022 (JP) 2022-018084
Apr. 5, 2022 (JP) 2022-063043

(51) Int. Cl. H01S 5/183; G01B 11/02; G02B 1/115

(52) U.S. Cl. CPC H01S 5/18388; G01B 11/026; G02B 1/115

(57) ABSTRACT

[Problem] Provided are a light-emitting device that can reduce the influence of the amorphous layer of an optical member on the optical characteristics, a method for manufacturing the light-emitting device, and a distance measurement device.

[Solution] The light-emitting device of the present disclosure includes a light-emitting element and an optical member that transmits light emitted from the light-emitting element, the optical member having an oxide film deposited with a uniform thickness of less than 2 μm on a surface on the exit side of the light.

### TECHNICAL FIELD

The present disclosure relates to a light-emitting device, a method for manufacturing a light-emitting device, and a distance measurement device.

### BACKGROUND ART

As one type of semiconductor laser, surface-emitting lasers such as vertical cavity surface-emitting lasers (VCSELs) have been known. Generally, in a light-emitting device utilizing a surface-emitting laser, a laser emits light from a mesa section, passes through a gallium arsenide (GaAs) substrate, and exits from the substrate. A lens shape is configured by dry etching, etc., on the surface of gallium arsenide in the exit portion.

### CITATION LIST

### Patent Literature

[PTL 1]

JP 2006-114753A

### SUMMARY

### Technical Problem

On the surface of gallium arsenide after etching, an amorphous layer mainly composed of gallium arsenide oxide and a strained layer are formed. However, the amorphous layer has a large variation in thickness, and the thicker the amorphous layer, the more the reflectance of the emitted beam is affected, and the optical characteristic varies.

Accordingly, the present disclosure provides a light-emitting device that can reduce the influence of the amorphous layer of an optical member on the optical characteristics, a method for manufacturing the light-emitting device, and a distance measurement device.

### Solution to Problem

In order to solve the above problem, the present disclosure provides a light-emitting device including a light-emitting element, and an optical member that transmits light emitted from the light-emitting element, the optical member having an oxide film deposited with a thickness of less than 2 μm on a surface on an exit side of the light.

The optical member may be gallium arsenide (GaAs), and
the oxide film may be a gallium arsenide (GaAs) chemical oxide film with a uniform thickness.

The oxide film does not need to contain halogen elements (Cl and F).

The optical member may further have an anti-reflection film on an upper side of the oxide film.

The anti-reflection film may be at least either of a silicon dioxide (SiO₂) film and a silicon nitride (Si₃N₄) film.

The optical member may be a lens.

The lens may be at least any one of a convex lens, a concave lens, a Fresnel lens, and a binary lens.

The light-emitting device may further include a substrate,
a plurality of light-emitting elements, each being said light-emitting element, may be disposed on a first surface side of the substrate, and
a plurality of lenses, each being said lens, may be disposed on a second surface side of the substrate.

In order to solve the above problem, according to the present disclosure, a method for manufacturing a light-emitting device with a plurality of light-emitting elements disposed on a first surface side of a substrate and a plurality of lenses disposed on a second surface side of the substrate, the method including:
a dry etching step of dry-etching an optical member of gallium arsenide (GaAs) to form a shape of the plurality of lenses;
a first step of removing, from a surface of the optical member after the dry etching, a predetermined layer using an acid or alkali solution that does not contain any oxidizing agent; and
a second step of forming, on an exit side of the optical member after the first step, a chemical oxide film deposited with a uniform thickness of less than 2 μm on a surface may be provided.

The second step may be a step of treating the optical member after the first step with a neutral solution containing an oxidant to form the chemical oxide film.

A chemical used in the first step may be at least any one of hydrogen chloride (HCl), hydrogen fluoride (HF), phosphoric acid (H₃PO₄), ammonia hydroxide (NH₄OH), tetramethylammonium chloride (TMAH), and ammonium sulfide (NH₄)₂S).

The neutral solution containing an oxidant may be at least either one of ozone (O₃) and hydrogen peroxide (H₂O₂).

Digital etching including forming an oxide layer and removing the oxide layer may be performed between the first step and the second step.

The digital etching may be performed multiple times.

The second step may be a step of forming the chemical oxide film by treating the optical member after the first step by a gas phase process of an ultraviolet ray (UV)/ozone (O₃) treatment or an oxygen (O₂) plasma treatment.

In order to solve the above problem, according to the present disclosure, a distance measurement device including a light-emitting unit including a plurality of light-emitting elements to emit light and being configured to irradiate a subject with light from the light-emitting elements;
a light-receiving unit configured to receive light reflected on the subject; and
a distance measurement unit configured to measure a distance to the subject based on light received by the light-receiving unit,
the light-emitting unit having
a substrate,
a plurality of light-emitting elements provided on a first surface side of the substrate, and
a plurality of lenses provided on a second surface side of the substrate, the lenses having a chemical oxide film deposited with a uniform thickness of less than 2 μm on a surface on an exit side of light from the light-emitting element may be provided.

### BRIEF DESCRIPTION OF DRAWINGS

FIG. 1 is a block diagram showing a structural example of a distance measurement device of a first embodiment.

FIG. 2 is a diagram for describing the structured light (STL) system of the first embodiment.

FIG. 3 is a cross-sectional view showing an example of the structure of the light-emitting device of the first embodiment.

FIG. 4 is a cross-sectional view showing the structure of the light-emitting device illustrated in FIG. 3.

FIG. 5 is a cross-sectional view showing a structural example of a light-emitting device 1 of the first embodiment.

FIG. 6 is a view illustrating the film structure on the back surface side of a lens.

FIG. 7 is a view schematically illustrating the film structure illustrated in FIG. 6 as a molecular structure.

FIG. 8 is a view illustrating one example of a manufacturing process of a lens according to the embodiment.

FIG. 9 is a TEM image of the film structure of a lens after dry etching.

FIG. 10 is a view illustrating the relationship between the amorphous layer and the reflectance of the emitted laser.

FIG. 11 is a view illustrating the film structure of a lens of a comparative example.

FIG. 12 is a view schematically illustrating the film structure of a lens of a comparative example as a molecular structure.

FIG. 13 is a view illustrating an example of a concave lens.

FIG. 14 is a view illustrating an example of a Fresnel lens.

FIG. 15 illustrates an example of another manufacturing process of an optical member formed in the LD chip.

FIG. 16 is a view illustrating an example of a manufacturing process further including a digital etching process.

### DESCRIPTION OF EMBODIMENTS

Embodiments of a light-emitting device, a manufacturing method of a light-emitting device, and a distance measurement device will be described below with reference to the drawings. Hereinafter, the major structural parts of the light-emitting device and the distance measurement device will be mainly described, but the light-emitting device and the distance measurement device may have structural components or functions that are not illustrated or described. The following description does not exclude components or functions that are not illustrated or described.

### First Embodiment

### (Configuration of Distance Measurement Device 101)

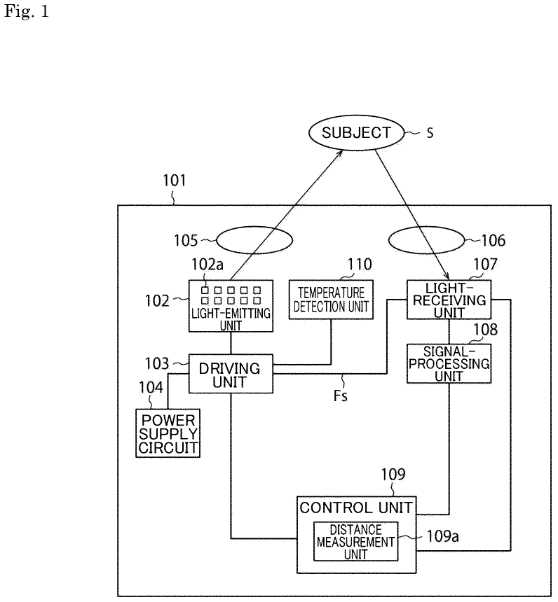

FIG. 1 is a block diagram showing a structural example of a distance measurement device 101 of a first embodiment.

As illustrated in the drawings, the distance measurement device 101 includes a light-emitting unit 102, a driving unit 103, a power supply circuit 104, a light-emitting side optical system 105, a light-receiving side optical system 106, a light-receiving unit 107, a signal processing unit 108, a control unit 109, and a temperature detection unit 110.

The light-emitting unit 102 emits light from a plurality of light sources. The light-emitting unit 102 of this example includes a light-emitting element 102a using a vertical cavity surface-emitting laser (VCSEL) as each light source and is configured such that the light-emitting elements 102a are arranged in a predetermined form, for example, a matrix.

The driving unit 103 is configured to have a power supply circuit for driving the light-emitting unit 102.

The power supply circuit 104 generates a power supply voltage of the driving unit 103 on the basis of, for example, an input voltage from a non-illustrated battery or the like disposed in the distance measurement device 101. The driving unit 103 drives the light-emitting unit 102 on the basis of the power supply voltage.

Light emitted from the light-emitting unit 102 irradiates a subject S, which is a target for measuring the distance, via the light-emitting side optical system 105. Then, the light irradiating the subject S as such and reflected on the subject S enters the light-receiving surface of the light-receiving unit 107 via the light-receiving side optical system 106.

For example, the light-receiving unit 107 is constituted of a light-receiving element such as a charge coupled device (CCD) sensor or a complementary metal oxide semiconductor (CMOS) sensor and receives the light reflected on the subject S and entering the light-receiving unit 107 via the light-receiving side optical system 106, as stated above, converts the light into electrical signals, and outputs the electrical signals.

The light-receiving unit 107 executes, for example, correlated double sampling (CDS) processing, automatic gain control (AGC) processing, and the like on the electrical signals obtained by photoelectrically converting the received light and further executes analog/digital (A/D) conversion processing of the electrical signals. The signals as digital data are then outputted to the signal-processing unit 108 provided at the latter stage.

Furthermore, the light-receiving unit 107 of this example outputs a frame synchronizing signal Fs to the driving unit 103. Thus, the driving unit 103 allows the light to be emitted from the light-emitting elements 102a in the light-emitting unit 102 at the timing corresponding to the frame period of the light-receiving unit 107.

For example, the signal-processing unit 108 is configured as a signal processor, for example, by a digital signal processor (DSP) and the like. The signal-processing unit 108 performs various kinds of signal processing on a digital signal inputted from the light-receiving unit 107.

For example, the control unit 109 is configured by a microcomputer that includes a central processing unit (CPU), read-only memory (ROM), and random access memory (RAM) or is configured to have an information processor, such as a DSP, and controls the driving unit 103 to control a light-emitting operation of the light-emitting unit 102 and controls a light-receiving operation of the light-receiving unit 107.

The control unit 109 has a function as a distance measurement unit 109a. The distance measurement unit 109a measures a distance to the subject S on the basis of a signal inputted via the signal-processing unit 108 (that is, a signal obtained by receiving the light reflected on the subject S). The distance measurement unit 109a of this example measures the distance to each portion of the subject S in order to make it possible to identify the three-dimensional shape of the subject S.

Here, a specific method for measuring the distance in the distance measurement device 101 will be explained later.

The temperature detection unit 110 detects the temperature of the light-emitting unit 102. The temperature detection unit 110 may be configured to detect a temperature, for example, using a diode.

In this example, information about a temperature detected by the temperature detection unit 110 is supplied to the driving unit 103, and, as a result, the driving unit 103 can drive the light-emitting unit 102 on the basis of the temperature information.

### (Regarding Distance Measuring Procedure)

For example, as the method for measuring the distance in the distance measurement device 101, a distance measurement method by a structured light (STL) method or a time of flight (ToF) method may be employed.

For example, the STL method is a method for measuring a distance on the basis of the image of the subject S irradiated with the light having a predetermined light/dark pattern such as a dot pattern or a grid pattern.

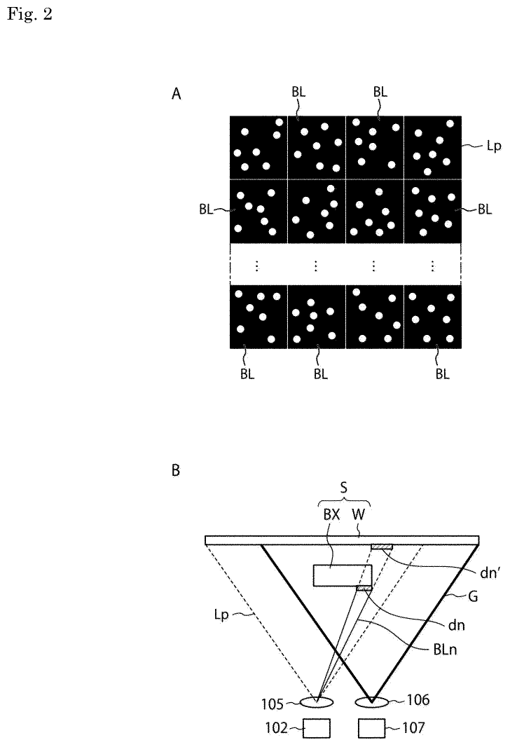

FIG. 2 is a diagram for describing the STL system of the first embodiment.

In the STL method, the subject S is irradiated with pattern light Lp, for example, by a dot pattern as illustrated in A in FIG. 2. The pattern light Lp is divided into a plurality of blocks BL, and different dot patterns are assigned to respective blocks BL (the dot patterns are not allowed to be the same among blocks B).

B in FIG. 2 is an explanatory diagram of the distance measurement principle of the STL method.

Here, an example in which a wall W and a box BX placed in front of the wall W are set as subjects S, and the subjects S are irradiated with pattern light Lp is explained. “G” in the figure schematically represents the angle of view of the light-receiving unit 107.

The “BLn” in the figure means the light of a certain block BL in pattern light Lp, and “dn” means a dot pattern of a block BLn projected on the light-receiving image by the light-receiving unit 107.

Here, if the box BX in front of the wall W is absent, the dot pattern of the block BLn in the received image is projected at the position of “dn” in the figure. That is, the positions where the pattern of the block BLn is projected are different in the received image between the case where the box BX is present and the case where the box BX is absent, and specifically, pattern distortion occurs.

The STL method is a method for determining the shape or depth of the subject S utilizing the phenomenon that the thus-projected pattern is distorted depending on the object shape of the subject S. Specifically, it is a method for determining the shape or depth of the subject S from the state of distortion of patterns.

For example, when the STL method is employed, an infrared ray (IR) receiving unit by a global shutter method is used as the light-receiving unit 107. Then, in the case of the STL method, the distance measurement unit 109a controls the driving unit 103 so that the light-emitting unit 102 emits pattern light, detects the distortion of patterns on the image signal obtained via a signal-processing unit 108, and calculates the distance on the basis of the state of distortion of the patterns.

Next, the ToF method is a method for measuring the distance to a target object by detecting the time of flight (time difference) until the light emitted from the light-emitting unit 102 is reflected on the target object and reaches the light-receiving unit 107.

If a so-called direct ToF (dTOF) method is employed as a ToF method, a single photon avalanche diode (SPAD) is used as the light-receiving unit 107, and the light-emitting unit 102 is pulse-driven. In this case, the distance measurement unit 109a calculates a time difference from emission to reception of light that is emitted from the light-emitting unit 102 and is received by the light-receiving unit 107 on the basis of a signal entering via the signal processing unit 108, and the distance measurement unit 109a calculates a distance to each portion of the subject S on the basis of the time difference and the speed of light.

If a so-called indirect ToF (iTOF) method (phase-contrast method) is employed as a ToF method, for example, a light-receiving unit that can receive IR is used as the light-receiving unit 107.

### (Light-Emitting Device of First Embodiment)

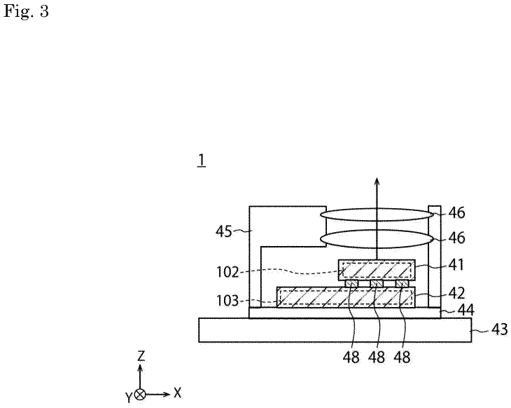

FIG. 3 is a cross-sectional view showing an example of the structure of the light-mitting device 1 of the first embodiment. The light-emitting device 1 of the present embodiment may be a part of the distance measurement device 101 or may be the distance measurement device 101 itself. The light-emitting device 1 of this example is provided with an LD chip 41 that includes a light-emitting unit 102, an LDD substrate 42 that includes the driving unit 103, a mounting substrate 43, a heat dissipation substrate 44, a correction lens-holding unit 45, one or more correction lenses 46, and bumps 48.

FIG. 3 illustrates the X-axis, the Y-axis, and the Z-axis that are perpendicular to one another. The X direction and the Y direction correspond to the lateral direction (horizontal direction), and the Z direction corresponds to the longitudinal direction (vertical direction). In addition, the +Z direction corresponds to the upward direction, and the −Z direction corresponds to the downward direction. The −Z direction may or may not coincide strictly with the direction of gravity.

For example, the mounting substrate 43 is a printed circuit board. On the mounting substrate 43, the light-receiving unit 107 and the signal-processing unit 108 illustrated in FIG. 1 may be disposed. The heat dissipation substrate 44 is a ceramic substrate, such as an aluminum oxide substrate or an aluminum nitride substrate. The LDD substrate 42 is disposed on the heat dissipation substrate 44, and the LD chip 41 is disposed on the LDD substrate 42.

The LDD substrate 42 is disposed on the heat dissipation substrate 44, and the LD chip 41 is disposed on the LDD substrate 42. As such, the LD chip 41 is disposed on the LDD substrate 42. This makes it possible to miniaturize the size of the mounting substrate 43. The LD chip 41 is disposed on the LDD substrate 42 via the bumps 48 and is electrically connected to the LDD substrate 42 via the bumps 48.

The correction lens-holding unit 45 is disposed on the heat dissipation substrate 44 so as to surround the LD chip 41, and one or more correction lenses 46 are held above the LD chip 41. These correction lenses 46 are included in the light-emitting side optical system 105 described above. The light emitted from the light-emitting unit 102 in the LD chip 41 is corrected by these correction lenses 46 and then irradiates the subject S described above. FIG. 3 illustrates two correction lenses 46 held by the correction lens-holding unit 45 as one example.

Hereinafter, the light-emitting device 1 of the present embodiment is explained as having a structure illustrated in FIG. 3. However, the structure of the light-emitting device 1 is not limited thereto.

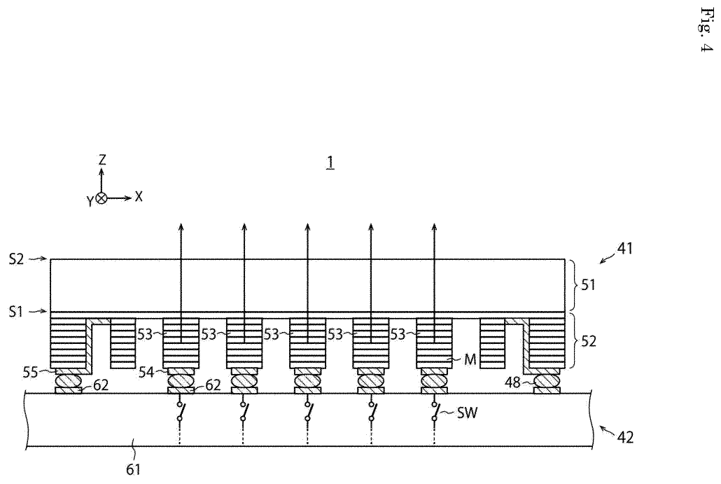

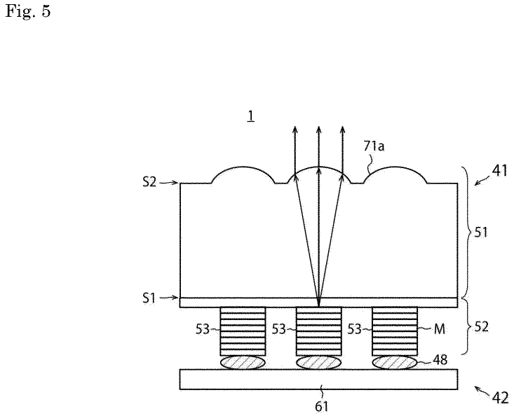

FIG. 4 is a cross-sectional view showing the structure of the light-emitting device 1 illustrated in FIG. 3. FIG. 4 illustrates the cross-section of the LD chip 41 and the LDD substrate 42 in the light-emitting device 1. As illustrated in FIG. 4, the LD chip 41 is provided with a substrate 51, a laminated film 52, a plurality of light-emitting elements 53, a plurality of anode electrodes 54, and a plurality of cathode electrodes 55, and the LDD substrate 42 is provided with a substrate 61 and a plurality of connection pads 62. The light-emitting element 53 illustrated in FIG. 4 is a specific example of the light-emitting element 102a described above. In FIG. 4, an illustration of the lens 71a, which will be described below, is omitted (see FIG. 5).

For example, the substrate 51 is a semiconductor substrate such as a GaAs (gallium arsenide) substrate. FIG. 4 illustrates the front surface S1 of the substrate 51 facing in the −Z direction and the back surface S2 of the substrate 51 facing in the +Z direction. The front surface S1 and the back surface S2 illustrated in FIG. 4 are perpendicular to the Z direction. The front surface S1 is an example of the first surface of the present disclosure, and the back surface S2 is an example of the second surface of the present disclosure.

The laminated film 52 includes a plurality of layers laminated on the front surface S1 of the substrate 51. Examples of these layers include an n-type semiconductor layer, an active layer, a p-type semiconductor layer, a light reflective layer, an insulation layer having a light exit window, and the like. The laminated film 52 includes a plurality of mesa portions M protruding in the −Z direction. A part of these mesa portions M constitutes a plurality of light-emitting element 53.

The light-emitting element 53 is disposed on the front surface S1 side of the substrate 51 as a part of the laminated film 52. The light-emitting element 53 of the present embodiment has a VCSEL structure and emits light in the +Z direction. The light emitted from the light-emitting element 53 passes through the substrate 51 from the front surface S1 to the back surface S2, as illustrated in FIG. 4, and enters the correction lens 46 (FIG. 3) described above from the substrate 51. As such, the LD chip 41 of the present embodiment is a back-emission-type VCSEL chip.

The anode electrode 54 is formed on the lower surface of the light-emitting element 53. The cathode electrode 55 is formed on the lower surface of the mesa portions M other than the light-emitting element 53 and extends to the lower surface of the laminated film 52 existing between mesa portions M. Each light-emitting element 53 emits light when an electric current flows between a corresponding anode electrode 54 and a corresponding cathode electrode 55.

As described above, the LD chip 41 is disposed on the LDD substrate 42 via the bumps 48 and is electrically connected to the LDD substrate 42 via the bumps 48. Specifically, the connection pad 62 is formed on the substrate 61 included in the LDD substrate 42, and the mesa portions M are placed on the connection pad 62 via the bumps 48. Each mesa portion M is disposed on the bumps 48 via the anode electrode 54 or the cathode electrode 55. For example, the substrate 61 is a semiconductor substrate, such as a silicon (Si) substrate.

The LDD substrate 42 includes the driving unit 103 that drives the light-emitting unit 102. FIG. 4 schematically illustrates a plurality of switches SW included in the driving unit 103. Each switch SW is electrically connected to a corresponding light-emitting element 53 via the bumps 48. The driving unit 103 of the present embodiment can control (turns on/off of) these switches SWs for each switch SW. Accordingly, the driving unit 103 can drive the plurality of light-emitting elements 53 for each individual light-emitting element 53. This makes it possible to precisely control the light emitted from the light-emitting unit 102. For example, only light is emitted from a light-emitting element 53 necessary for measuring a distance. Such individual control of a light-emitting element 53 can be achieved by placing the LDD substrate 42 below the LD chip 41 because the electrical connection between each light-emitting element 53 and a corresponding switch SW becomes easier.

FIG. 5 is a cross-sectional view showing a structural example of the light-emitting device 1 of the first embodiment. FIG. 5 illustrates the cross-sections of the LD chip 41 and the LDD substrate 42 in the light-emitting device 1. As described above, the LD chip 41 is provided with a substrate 51, a laminated film 52, a plurality of light-emitting elements 53, a plurality of anode electrodes 54, and a plurality of cathode electrodes 55, and the LDD substrate 42 is provided with a substrate 61 and a plurality of connection pads 62. However, an illustration of the anode electrode 54, the cathode electrode 55, and the connection pad 62 is omitted in FIG. 5.

As illustrated in FIG. 5, the LD chip 41 of the present embodiment includes a plurality of light-emitting elements 53 on the front surface S1 side of the substrate 51 and a plurality of lenses 71a on the back surface S2 side of the substrate 51.

The lenses 71a are arranged in a two-dimensional array, as with the light-emitting elements 53. The lenses 71a of the present embodiment correspond one-to-one to the light-emitting elements 53, and each lens 71a is arranged in the +Z direction of one light-emitting element 53. The lens 71a of the present embodiment is arranged, for example, in a square grid, but may be arranged in other layouts.

Furthermore, the lens 71a of the present embodiment is disposed as a part of the substrate 51 on the back surface S2 of the substrate 51, as illustrated in FIG. 5.

Specifically, the lens 71a of the present embodiment is a convex lens and formed as a part of the substrate 51 by etching the back surface S2 of the substrate 51 into a convex shape, which will be described below. According to the present embodiment, the lens 71a may be easily formed by forming the lens 71a by etching the substrate 51. The lens 71a of the present embodiment may be a lens other than a convex lens and, for example, may be a concave lens, a binary lens, a Fresnel lens, or the like.

The light emitted from the plurality of light-emitting elements 53 passes through the substrate 51 from the front surface S1 to the back surface S2 of the substrate 51 and enters the plurality of lenses 71a. In the present embodiment, the light emitted from each light-emitting element 53 enters one corresponding lens 71a. This allows the light emitted from the plurality of light-emitting element 53 to be shaped for each individual lens 71a. The light that has passed through the plurality of lenses 71a passes through the correction lens 46 (FIG. 3) and irradiates the subject S (FIG. 1).

For example, the width w of the lens 71a is 10 to 30 μm. The widths w of the lens 71a may be the same for all lenses 71a or may be different for each lens 71a. The width w of the lens 71a of the present embodiment is set to about 20 μm.

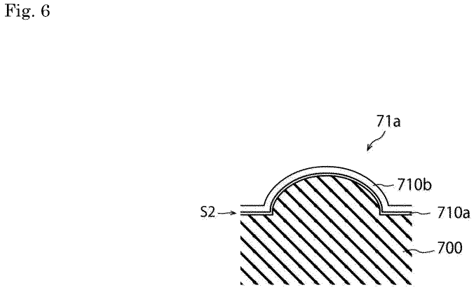

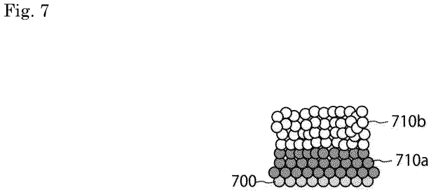

FIG. 6 is a view illustrating the film structure on the back surface S2 side of a lens 71a. That is, FIG. 6 illustrates the film structure of the lens 71a on the back surface S2 side of the substrate 51 (see FIG. 5). FIG. 7 is a view schematically illustrating the film structure illustrated in FIG. 6 as a molecular structure. As illustrated in FIGS. 6 and 7, the lens 71a has an oxide film 710a and an anti-reflection film 710b on the surface of a bulk 700. The atomic composition ratio on the lens surface of the lens 71a according to the present embodiment satisfies 0.5 or more in terms of a Ga/As ratio. Details of the method for manufacturing the film structure will be described later.

The oxide film 710a is a GaAs chemical oxide film. This GaAs chemical oxide film is uniformly formed at the interface between the surface of the GaAs lens 71a and the anti-reflection film 710b. Furthermore, the GaAs chemical oxide film is formed in a thickness of 2 nanometers (nm) or less. Furthermore, the oxide film 710a is formed on the lens surface of the lens 71a of the present embodiment so that halogen elements (Cl and F) used in dry etching do not exist. The term “uniform(ly)” in the present embodiment means the variation of less than ±20 percent, for example. For example, for 2 nm, a range from 1.6 nm to 2.4 nm is regarded as uniform.

The anti-reflection film 710b is silicon oxide and, for example, a thin film of silicon dioxide SiO₂. The thin film of silicon dioxide SiO₂ is formed by a method such as sputtering, a chemical transport method, and a plasma deposition method. Alternatively, the anti-reflection film 710b may be a silicon nitride film Si₃N₄. The silicon nitride film is formed on the oxide film 710a of the lens 71a by reactive sputtering or thermal decomposition of a SiH₄·NH₃ system or a SiCl₄·NH₃ system. A silicon nitride film Si₃N₄ is a chemically stable insulation substance, as with silicon dioxide SiO₂.

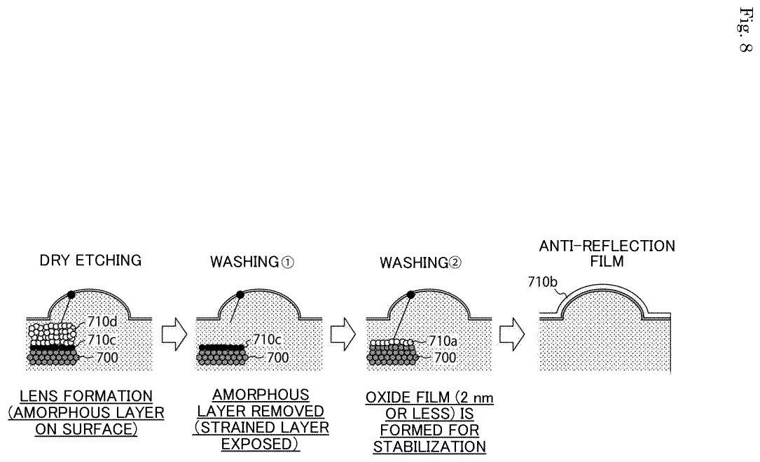

FIG. 8 is a diagram illustrating an example of a manufacturing process of a lens 71a according to the present embodiment.

### (Dry Etching)

First, the lens shape of the lens 71a is formed by dry etching. In this step, a strained layer 710c and an amorphous layer 710d constituted of GaAs oxide are formed in the process of dry etching.

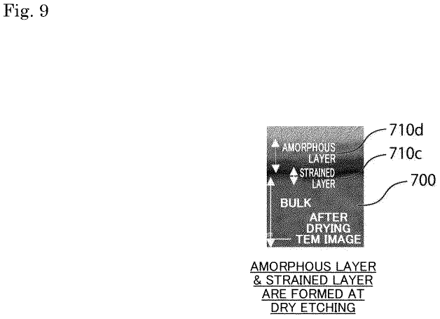

FIG. 9 is a transmission electron microscope (TEM) image of the film structure of a lens 71a after dry etching. As illustrated in FIG. 9, a strained layer 710c and an amorphous layer 710d constituted by GaAs oxide are formed on the surface of the bulk 700 in the lens 71a after dry etching. The amorphous layer 710d formed by this dry etching has a large variation in thickness and has a variation of about 3 to 10 nm in thickness. Furthermore, GaAs oxide formed in the process of dry etching contains halogen elements (Cl and F) used in the process of dry etching, and the optical characteristics may further vary due to the influence thereof.

### (First Washing Process)

As illustrated in FIG. 8 again, washing using an acid or alkali solution that does not contain any oxidizing agent is performed in the first washing process. The amorphous layer 710d is constituted by oxides and thus can be removed by the washing process. Thus, the washing process using an acid or alkali solution that does not contain any oxidizing agent, which suppresses the influence on the bulk 700, is effective. More specifically, washing is performed using a chemical species such as hydrogen chloride (HCl), hydrogen fluoride (HF), phosphoric acid (H₃PO₄), ammonia hydroxide (NH₄OH), tetramethylammonium chloride (TMAH), or ammonium sulfide (NH₄)₂S. At least the amorphous layer 710d is removed in the first washing process. This washing removes the film containing a halogen element (Cl and F). Thus, the variation in optical characteristics is suppressed due to the film containing halogen elements (Cl and F). The strained layer 710c may also be removed in the first washing process.

However, simply removing the amorphous layer 710d would expose the strained layer 710c, the bulk 700, and the like. The strained layer 710c is very highly reactive and forms aggregates by a reaction with the air. Furthermore, the bulk 700 may produce a deteriorated matter when the anti-reflection film 710b is deposited.

### (Second Washing Process)

Thus, in the second washing process, a GaAs chemical oxide film is formed as an oxide film 710a. In the second washing process, washing is performed using a neutral solution containing an oxidant (ozone (O₃), hydrogen peroxide (H₂O₂)), or the like. Washing with ultra-pure water is performed between these washing processes, and the substrate may be dried. A GaAs chemical oxide film formed using a neutral solution containing an oxidant is formed with a uniform thickness of less than 2 μm. Furthermore, a GaAs chemical oxide film deposited by washing with a neutral solution containing an oxidant does not contain halogen elements (Cl and F) used in the process of dry etching, and, therefore, the influence of halogen elements is suppressed.

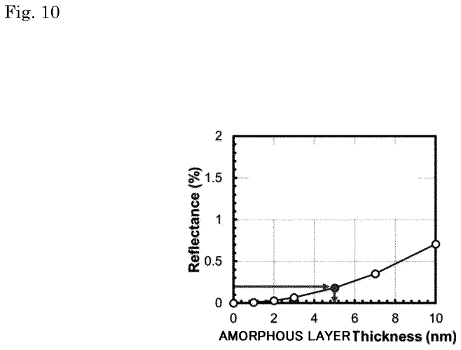

FIG. 10 is a view illustrating the relationship between the amorphous layer and the reflectance of the emitted laser. The abscissa axis represents the thickness of the amorphous layer, and the ordinate axis represents reflectance. As illustrated in FIG. 10, the thicker the amorphous layer, the higher the reflectance. The reflectance of the emitted laser is affected. The oxide film 710a formed in the present embodiment is formed using a neutral solution containing an oxidant and can be stably deposited with a uniform thickness of less than 2 μm. Thus, with regard to the thickness, the oxide film 710a is deposited such that the reflectance of the emitted laser can be more suppressed.

### (Deposition Process of Anti-Reflection Film)

An anti-reflection film 710b is deposited after the deposition of the oxide film 710a. The oxide film 710a suppresses the influence of the deposition process of the anti-reflection film 710b on the strained layer 710c, the bulk 700, and the like. For example, the anti-reflection film 710b can be formed by a method such as a chemical transport method. The oxide film 710a and the anti-reflection film 710b illustrated in FIG. 6 are deposited in this way.

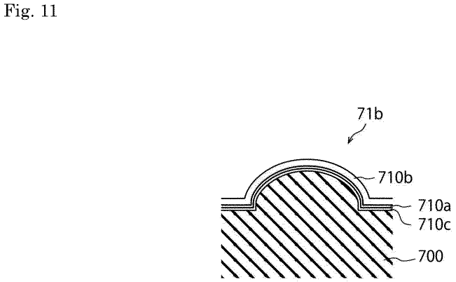

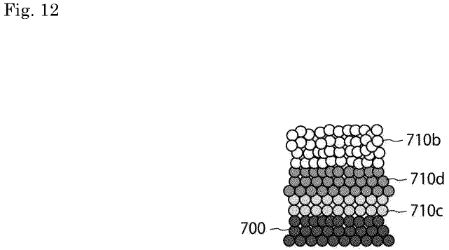

FIG. 11 is a view illustrating the film structure of a lens 71b of a comparative example. FIG. 12 is a view schematically illustrating the film structure of the lens 71b as a schematic molecular structure. The lens 71b of a comparative example is a common lens formed by (dry etching) illustrated, for example, in FIG. 8. Thus, as stated above, in the lens 71b, the strained layer 710c and the amorphous layer 710d constituted by GaAs oxide are formed on the surface of the bulk 700. The amorphous layer 710d formed by dry etching has a large thickness variation and has a variation in thickness of 3 to 10 nm.

The amorphous layer 710d contains halogen elements (Cl and F) used in the process of dry etching. As illustrated in FIG. 10, the thicker the amorphous layer, the higher the reflectance, and in the comparative example, the reflectance of the emitted laser is more reduced. Since the amorphous layer 710d has a variation in thickness of about 3 to 10 nm, variation in reflectance also occurs. As such, the optical characteristics of the lens 71b may vary by the influence of the amorphous layer 710d. In contrast, the oxide film 710a according to the present embodiment is formed using a neutral solution containing an oxidant, as described above, and thus deposited with a uniform thickness of less than 2 μm, which suppresses a variation in optical characteristics. Furthermore, this oxide film 710a does not contain halogen elements (Cl and F) used in the process of dry etching, and the influence of the halogen elements is also suppressed in the oxide film 710a of the present embodiment.

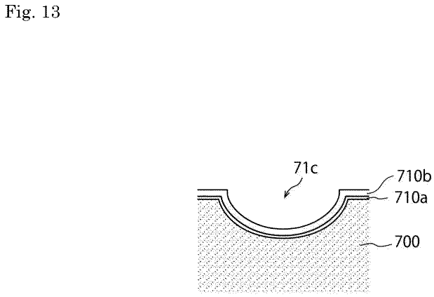

FIG. 13 is a view illustrating an example of a concave lens. Also, in the case of the concave lens 71c, the oxide film 710a and the anti-reflection film 710b can be formed on a gallium arsenide (GaAs) substrate through a similar production process to FIG. 8. A plurality of concave lenses 71c are formed on the LD chip 41 in the light-emitting device 1 illustrated in FIG. 4. As a result, light emitted from the plurality of light-emitting elements 53 passes through the substrate 51 from the front surface S1 to the back surface S2 of the substrate 51 and enters the above plurality of concave lenses 71c. In the present embodiment, light emitted from each light-emitting element 53 enters one corresponding concave lens 71c. This allows the light emitted from the plurality of light-emitting element 53 to be shaped for each individual lens 71c. The light that has passed through the above plurality of lenses 71a passes through the correction lens 46 (FIG. 3) and irradiates the subject S (FIG. 1).

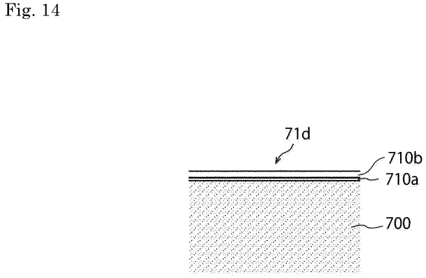

FIG. 14 is a view illustrating an example of a Fresnel lens. Also, in the case of the Fresnel lens 71d, the oxide film 710a and the anti-reflection film 710b can be formed on a gallium arsenide (GaAs) substrate in a similar production process to FIG. 8. The Fresnel lens 71d is formed on the LD chip 41 in the light-emitting device 1 illustrated in FIG. 4. As a result, light emitted from the plurality of light-emitting elements 53 passes through the substrate 51 from the front surface S1 to the back surface S2 of the substrate 51 and enters the above plurality of Fresnel lenses 71d. The light that has passed through the Fresnel lenses 71d passes through the correction lens 46 (FIG. 3) and irradiates the subject S (FIG. 1).

As such, the optical member formed in the LD chip 41 may be a lens other than a convex lens and, for example, may be a concave lens, a binary lens, a Fresnel lens, or the like. On these optical members, the oxide film 710a and the anti-reflection film 710b are formed, and the variation of optical properties is suppressed.

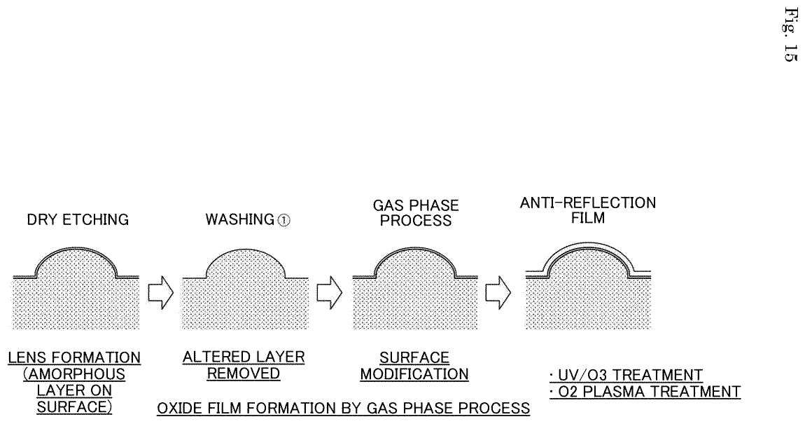

FIG. 15 illustrates an example of another manufacturing process of an optical member formed in the LD chip 41. FIG. 15 differs from FIG. 8 in that the surface of the optical member is modified by a “gas phase process” instead of the “second washing process” in FIG. 8. The following describes the differences from the manufacturing process illustrated in FIG. 8. As illustrated in FIG. 15, the oxidation process is performed in a gas phase process, not in a liquid process. More specifically, the oxide film 710a is deposited by an ultraviolet ray (UV)/ozone (O₃) treatment or an oxygen (O₂) plasma treatment. Also, in the gas phase process, the oxide film 710a according to the present embodiment is deposited with a uniform thickness of less than 2 μm, which suppresses a variation in optical characteristics. Furthermore, this oxide film 710a does not contain halogen elements (Cl and F) used in the process of dry etching, and the influence of the halogen elements is also suppressed in the oxide film 710a of the present embodiment.

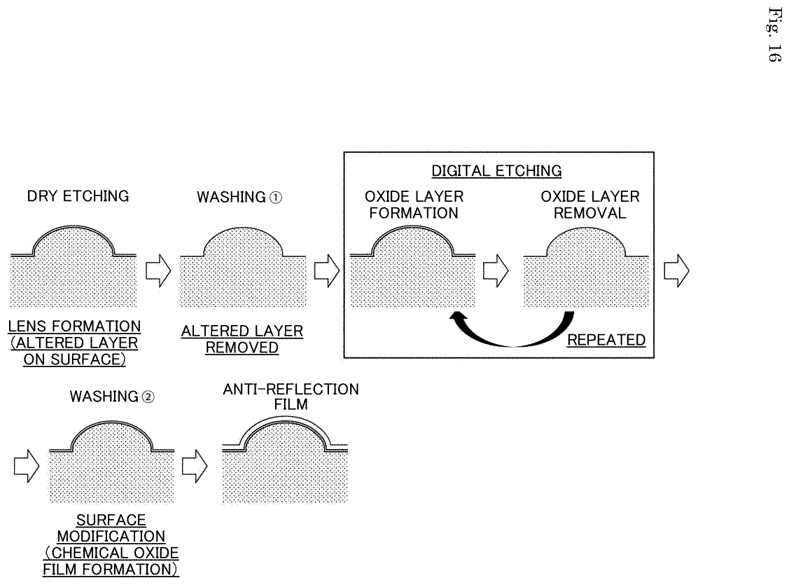

FIG. 16 is a view illustrating an example of a manufacturing process further including an additional digital etching process. This example is different in that a digital etching process is added between the “first washing process” and the “second washing process”. The following describes the differences from the manufacturing process illustrated in FIG. 8.

As illustrated in FIG. 16, a digital etching process is a process repeating the “oxide layer formation process” and the “oxide layer removal process”.

### (Oxide Layer Formation Process)

The oxide layer formation process forms a GaAs chemical oxide film. For example, an optical member is washed with a neutral solution containing an oxidant (ozone (O₃), hydrogen peroxide (H₂O₂), or the like. Washing with ultra-pure water is performed between these washing processes, and the substrate may be dried. The GaAs chemical oxide film formed using a neutral solution containing an oxidant is formed with a uniform thickness of less than 2 μm.

### (Oxide Layer Removal Process)

In the oxide layer removal process, washing with an acid or alkali solution that does not contain any oxidizing agent is performed. For example, washing is performed using a chemical species such as hydrogen chloride (HCl), hydrogen fluoride (HF), phosphoric acid (H₃PO₄), ammonia hydroxide (NH₄OH), tetramethylammonium chloride (TMAH), ammonium sulfide (NH₄)₂S, or the like. For example, the “oxide layer formation process” and the “oxide layer removal process” are repeated about five times. This makes it possible to slightly etch GaAs and remove the strained layer 710c while suppressing the penetration into the bulk 700.

As stated above, the optical member of the LD chip 41 in the light-emitting device 1 of the present embodiment has an oxide film 710a deposited with a uniform thickness of less than 2 μm. This suppresses the reflection on the amorphous layer and the variation in optical characteristics. Thus, it is possible to reduce the influence of the optical properties of the amorphous layer of the optical member in the LD chip 41 on the light-emitting device 1.

Although the light-emitting device 1 of the present embodiment is used as a light source of the distance measurement device 101, it may be used in other forms. For example, the light-emitting device 1 of these embodiments may be used as a light source of an optical device, such as a printer, or may be used as an illumination device.

While embodiments of the present disclosure have been described above, these embodiments may be implemented with various modifications without departing from the spirit of the present disclosure.

Here, the present disclosure may have the following configuration.

(1)

A light-emitting device including:
a light-emitting element; and
an optical member that transmits light emitted from the light-emitting element, the optical member having an oxide film deposited with a thickness of less than 2 μm on a surface on an exit side of the light.
   (2)

The light-emitting device according to (1), wherein
the optical member is gallium arsenide (GaAs), and
the oxide film is a gallium arsenide (GaAs) chemical oxide film with a uniform thickness.
   (3)

The light-emitting device according to (2), wherein the oxide film does not contain halogen elements (Cl and F).

(4)

The light-emitting device according to (3), wherein the optical member further has an anti-reflection film on an upper side of the oxide film.

(5)

The light-emitting device according to (4), wherein the anti-reflection film is at least either of a silicon dioxide (SiO₂) film and a silicon nitride film (Si₃N₄) film.

(6)

The light-emitting device according to (5), wherein the optical member is a lens.

(7)

The light-emitting device according to (6), wherein the lens is at least any one of a convex lens, a concave lens, a Fresnel lens, and a binary lens.

(8)

The light-emitting device according to (6), further including a substrate, wherein
a plurality of light-emitting elements, each being said light-emitting element, are disposed on a first surface side of the substrate, and
a plurality of lenses, each being said lens, are disposed on a second surface side of the substrate.
   (9)

A method for manufacturing a light-emitting device with a plurality of light-emitting elements disposed on a first surface side of a substrate and a plurality of lenses disposed on a second surface side of the substrate, the method including: a dry etching step of dry-etching an optical member of gallium arsenide (GaAs) to form a shape of the plurality of lenses;
a first step of removing, from a surface of the optical member after the dry etching, a predetermined layer using an acid or alkali solution that does not contain any oxidizing agent; and
a second step of forming, on a surface of an exit side of the optical member after the first step, a chemical oxide film deposited with a uniform thickness of less than 2 μm.
   (10)

The method for manufacturing a light-emitting device according to (9), wherein the second step is a step of treating the optical member after the first step with a neutral solution containing an oxidant to form the chemical oxide film.

(11)

The method for manufacturing a light-emitting device according to (10), wherein a chemical used in the first step is at least any one of hydrogen chloride (HCl), hydrogen fluoride (HF), phosphoric acid (H₃PO₄), ammonia hydroxide (NH₄OH), tetramethylammonium chloride (TMAH), and ammonium sulfide (NH₄)₂S.

(12)

The method for manufacturing a light-emitting device according to (11), wherein the neutral solution containing an oxidant is at least either one of ozone (O₃) and hydrogen peroxide (H₂O₂).

(13)

The method for manufacturing a light-emitting device according to (9), wherein digital etching including forming an oxide layer and removing the oxide layer is performed between the first step and the second step.

(14)

The method for manufacturing a light-emitting device according to (13), wherein the digital etching is performed multiple times.

(15)

The method for producing a light-emitting device according to (9), wherein the second step is a step of forming the chemical oxide film by treating the optical member after the first step by a gas phase process of an ultraviolet ray (UV)/ozone (O₃) treatment or an oxygen (O₂) plasma treatment.

(16)

A distance measurement device including:
a light-emitting unit including a plurality of light-emitting elements to emit light and being configured to irradiate a subject with light from the light-emitting elements;
a light-receiving unit configured to receive light reflected on the subject; and
a distance measurement unit configured to measure a distance to the subject based on light received by the light-receiving unit,
the light-emitting unit having
a substrate,
a plurality of light-emitting elements provided on a first surface side of the substrate, and
a plurality of lenses provided on a second surface side of the substrate,
the lenses having a chemical oxide film deposited with a uniform thickness of less than 2 μm on a surface of an exit side of light from the light-emitting element.

### REFERENCE SIGNS LIST

1 Light-emitting apparatus
41 LD chip
42 LDD substrate
53 Light-emitting element
71a, 71c, 71d Lens
101 Distance measurement device
102 Light-emitting unit
102a Light-emitting element
710a Oxide film
710b Anti-reflection film

1. A light-emitting device comprising:
a light-emitting element; and
an optical member that transmits light emitted from the light-emitting element,
the optical member having an oxide film deposited with a thickness of less than 2 nm on a surface on an exit side of the light.

2. The light-emitting device according to claim 1, wherein
the optical member is gallium arsenide (GaAs), and
the oxide film is a gallium arsenide (GaAs) chemical oxide film with a uniform thickness.

3. The light-emitting device according to claim 2, wherein the oxide film does not contain halogen elements (Cl and F).

4. The light-emitting device according to claim 3, wherein the optical member further has an anti-reflection film on an upper side of the oxide film.

5. The light-emitting device according to claim 4, wherein the anti-reflection film is at least either of a silicon dioxide (SiO₂) film and a silicon nitride (Si₃N₄) film.

6. The light-emitting device according to claim 5, wherein the optical member is a lens.

7. The light-emitting device according to claim 6, wherein the lens is at least any one of a convex lens, a concave lens, a Fresnel lens, and a binary lens.

8. The light-emitting device according to claim 6, further comprising a substrate, wherein a plurality of light-emitting elements, each being said light-emitting element, are disposed on a first surface side of the substrate, and
a plurality of lenses, each being said lens, are disposed on a second surface side of the substrate.

9. A method for manufacturing a light-emitting device with a plurality of light-emitting elements disposed on a first surface side of a substrate and a plurality of lenses disposed on a second surface side of the substrate, the method comprising:
a dry etching step of dry-etching an optical member of gallium arsenide (GaAs) to form a shape of the plurality of lenses;
a first step of removing, from a surface of the optical member after the dry etching, a predetermined layer using an acid or alkali solution that does not contain any oxidizing agent; and
a second step of forming, on an exit side of the optical member after the first step, a chemical oxide film deposited with a uniform thickness of less than 2 nm on a surface.

10. The method for manufacturing a light-emitting device according to claim 9, wherein the second step is a step of treating the optical member after the first step with a neutral solution containing an oxidant to form the chemical oxide film.

11. The method for manufacturing a light-emitting device according to claim 10, wherein a chemical used in the first step is at least any one of hydrogen chloride (HCl), hydrogen fluoride (HF), phosphoric acid (H₃PO₄), ammonia hydroxide (NH₄OH), tetramethylammonium chloride (TMAH), and ammonium sulfide (NH₄)₂S.

12. The method for manufacturing a light-emitting device according to claim 11, wherein the neutral solution containing an oxidant is at least either one of ozone (O₃) and hydrogen peroxide (H₂O₂).

13. The method for manufacturing a light-emitting device according to claim 9, wherein digital etching including forming an oxide layer and removing the oxide layer is performed between the first step and the second step.

14. The method for manufacturing a light-emitting device according to claim 13, wherein the digital etching is performed multiple times.

15. The method for manufacturing a light-emitting device according to claim 9, wherein the second step is a step of forming the chemical oxide film by treating the optical member after the first step by a gas phase process of an ultraviolet ray (UV)/ozone (O₃) treatment or an oxygen (O₂) plasma treatment.

16. A distance measurement device comprising:
a light-emitting unit including a plurality of light-emitting elements to emit light and being configured to irradiate a subject with light from the light-emitting elements;
a light-receiving unit configured to receive light reflected on the subject; and
a distance measurement unit configured to measure a distance to the subject based on light received by the light-receiving unit,
the light-emitting unit having
a substrate,
a plurality of light-emitting elements provided on a first surface side of the substrate, and
a plurality of lenses provided on a second surface side of the substrate,
the lenses having a chemical oxide film deposited with a uniform thickness of less than 2 nm on a surface on an exit side of light from the light-emitting element.
